(19) United States
(12) Patent Application Publication
(10) Pub. No.: US 2023/0005784 A1
(43) Pub. Date: Jan. 5, 2023

(54) SUBSTRATE TREATING APPARATUS AND SUBSTRATE TREATING METHOD

(71) Applicant: SEMES CO., LTD., Cheonan-si (KR)

(72) Inventors: Gwang Min BU, Pohang-si (KR); Sun June KIM, Seoul (KR)

(73) Assignee: SEMES CO., LTD., Cheonan-si (KR)

(21) Appl. No.: 17/854,661

(22) Filed: Jun. 30, 2022

(30) Foreign Application Priority Data
Jul. 2, 2021 (KR) 10-2021-0087214

(51) Int. Cl. H01L 21/687; H01L 21/67; H01J 37/32; C23C 16/455; H01L 21/683

(52) U.S. Cl. CPC H01L 21/68714; H01L 21/67023; H01J 37/3244; C23C 16/45551; H01L 21/6831

(57) ABSTRACT

The inventive concept provides a substrate treating apparatus. The substrate treating apparatus includes a chamber having a space for treating a substrate therein; a support unit for supporting the substrate within the chamber; and an insulation member having a space of a predetermined volume therein.

### CROSS-REFERENCE TO RELATED APPLICATIONS

A claim for priority under 35 U.S.C. § 119 is made to Korean Patent Application No. 10-2021-0087214 filed on Jul. 2, 2021, in the Korean Intellectual Property Office, the entire contents of which are hereby incorporated by reference.

### TECHNICAL FIELD

Embodiments of the inventive concept described herein relate to a substrate treating apparatus and a substrate treating method, more specifically, a substrate treating apparatus and a substrate treating method capable of adjusting an impedance of a chamber at which a substrate is treated.

### BACKGROUND

The semiconductor manufacturing process may include a process of treating a substrate using a plasma. For example, during the semiconductor manufacturing process, an etching process may remove a thin film on the substrate using the plasma.

An isolator may be positioned below an electrostatic chuck supporting the substrate. According to an embodiment, the isolator may be composed of an Al₂O₃ having a value between a dielectric constant of 9.4 to 10.5. Once sintered, the isolator has its own dielectric constant. However, the dielectric constant varies according to a sintering method and a material, and also becomes a factor that limits a chamber TTTM. In addition, if the isolator once installed is not replaced, an impedance of the chamber is fixed, and it is difficult to match an impedance level required during the process.

### SUMMARY

Embodiments of the inventive concept provide a substrate treating apparatus capable of adjusting an impedance of a chamber.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having a space for treating a substrate therein; a support unit for supporting the substrate within the chamber; and an insulation member having a space of a predetermined volume therein.

In an embodiment, the space is empty.

In an embodiment, a fluid is provided in a predetermined volume at the space.

In an embodiment, the space is filled with a fluid.

In an embodiment, the substrate treating apparatus further includes an adjusting unit for adjusting an injection amount of a fluid injected into the space.

In an embodiment, the adjusting unit adjusts the injection amount of the fluid so an impedance of the chamber is adjusted.

In an embodiment, the adjusting unit is a chiller or a pump.

The inventive concept provides a substrate treating apparatus. The substrate treating apparatus includes a chamber having a space for treating a substrate therein; a support unit for supporting the substrate within the chamber, and including an electrostatic chuck for adsorbing the substrate using an electrostatic force; a gas supply unit for supplying a treating gas within the space; a plasma source for generating a plasma from the treating gas; and an insulation member positioned below the electrostatic chuck, and having a space of a predetermined volume therein.

In an embodiment, the space is empty.

In an embodiment, a fluid is provided in a predetermined volume at the space.

In an embodiment, the space is filled with a fluid.

In an embodiment, the substrate treating apparatus further includes an adjusting unit for adjusting an injection amount of a fluid injected to the space.

In an embodiment, the adjusting unit adjusts the injection amount of the fluid so an impedance of the chamber is adjusted.

In an embodiment, the adjusting unit is a chiller or a pump.

The inventive concept provides a substrate treating method using the substrate treating apparatus. The substrate treating method includes injecting a fluid to the space

In an embodiment, the substrate treating method of includes adjusting an impedance of the chamber by adjusting an injection amount of the fluid.

In an embodiment, an impedance adjusting of the chamber is simultaneously adjusted with a substrate treatment.

According to an embodiment of the inventive concept, an impedance of a chamber may be effectively controlled.

According to an embodiment of the inventive concept, a life of a chamber may be increased.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 is a cross-sectional view illustrating the substrate treating apparatus according to an embodiment of the inventive concept in more detail.

FIG. 3 illustrates an embodiment of a space formation according to an embodiment of the inventive concept.

FIG. 4 illustrates an ER change for each inner space within an insulation member.

FIG. 5 illustrates a CD change and a bias change for each inner space within the insulation member.

FIG. 6 illustrates a space within the insulation member according to various embodiments of the inventive concept.

FIG. 7 is a flowchart illustrating a substrate treating method according to an embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

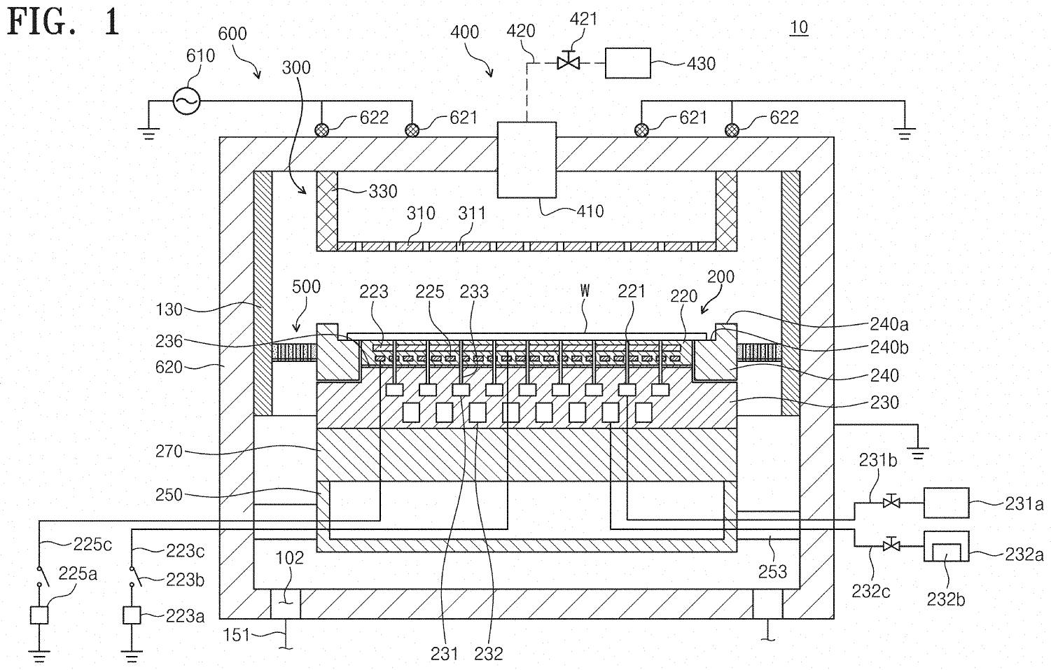

FIG. 1 is an exemplary view illustrating a substrate treating apparatus according to an embodiment of the inventive concept.

FIG. 1 illustrates a substrate treating apparatus W using a capacitively coupled plasma (CCP) treating method. Referring to FIG. 1, the substrate treating apparatus 10 treats the substrate W using a plasma. For example, the substrate treating apparatus 10 may perform an etching process on the substrate W. The substrate treating apparatus 10 may include a chamber 620, a substrate support unit 200, a shower head 300, a gas supply unit 400, an exhaust baffle 500, and a plasma generation unit 600.

The chamber 620 may provide a treating space in which a substrate treating process is performed. The chamber 620 may have a treating space therein and may be provided in a sealed shape. The chamber 620 may be made of a metal material. The chamber 620 may be made of an aluminum material. The chamber 620 may be grounded. An exhaust hole 102 may be formed on a bottom surface of the chamber 620. The exhaust hole 102 may be connected to an exhaust line 151. A reaction by-product generated during the process and a gas remaining in an inner space of the chamber may be discharged to an outside through the exhaust line 151. An inside of the chamber 620 may be depressurized to a predetermined pressure by the exhaust process.

According to an embodiment, a liner 130 may be provided inside the chamber 620. The liner 130 may have a cylindrical shape with an open top surface and an open bottom surface. The liner 130 may be provided to be in contact with an inner surface of the chamber 620. The liner 130 may protect an inner wall of the chamber 620 to prevent the inner wall of the chamber 620 from being damaged by the arc discharge. In addition, it is possible to prevent impurities generated during the substrate treating process from being deposited on the inner wall of the chamber 620. Selectively, the liner 130 may not be provided.

The substrate support unit 200 may be positioned inside the chamber 620. The substrate support unit 200 may support the substrate W. The substrate support unit 200 may include an electrostatic chuck 210 that sucks the substrate W using an electrostatic force. Alternatively, the substrate support unit 200 may support the substrate W in various ways such as a mechanical clamping. Hereinafter, the substrate support unit 200 including the electrostatic chuck 210 will be described.

The substrate support unit 200 may include an electrostatic chuck 210, a bottom cover 250, and a plate 270. The substrate support unit 200 may be positioned inside the chamber 620 to be upwardly spaced apart from a bottom surface of the chamber 620.

The electrostatic chuck 210 may include a dielectric plate 220, a body 230, and a focus ring 240. The electrostatic chuck 210 may support the substrate W. The dielectric plate 220 may be positioned at a top end of the electrostatic chuck 210. The dielectric plate 220 may be provided as a disk-shaped dielectric substance. The substrate W may be disposed on a top surface of the dielectric plate 220. The top surface of the dielectric plate 220 may have a radius smaller than that of the substrate W. Therefore, an edge region of the substrate W may be located outside the dielectric plate 220.

The dielectric plate 220 may include a first electrode 223, a heating unit 225, and a first supply fluid channel 221 therein. The first supply fluid channel 221 may be provided from a top surface to a bottom surface of the dielectric plate 210. A plurality of first supply fluid channel 221 are formed to be spaced apart from each other, and may be provided as a passage through which a heat transfer medium is supplied to a bottom surface of the substrate W.

The first electrode 223 may be electrically connected to a first power source 223a. The first power source 223a may include a DC power.

A switch 223b may be installed between the first electrode 223 and the first power source 223a. The first electrode 223 may be electrically connected to the first power source 223a by on/off of the switch 223b. When the switch 223b is turned on, a DC current may be applied to the first electrode 223. An electrostatic force is applied between the first electrode 223 and the substrate W by a current applied to the first electrode 223, and the substrate W may be sucked to the dielectric plate 220 by the electrostatic force.

The heating unit 225 may be located below the first electrode 223. The heating unit 225 may be electrically connected to the second power source 225a. The heating unit 225 may generate a heat by resisting a current applied from the second power source 225a. A generated heat may be transferred to the substrate W through the dielectric plate 220. The substrate W may be maintained at a predetermined temperature by the heat generated by the heating unit 225. The heating unit 225 may include a spiral shape coil.

The body 230 may be positioned below the dielectric plate 220. The bottom surface of the dielectric plate 220 and the top surface of the body 230 may be bonded by an adhesive 236. The body 230 may be made of an aluminum material. The top surface of the body 230 may be positioned such that a central region is higher than the edge region. The central region of the top surface of the body 230 has an area corresponding to the bottom surface of the dielectric plate 220 and may be adhered to the bottom surface of the dielectric plate 220. The body 230 may have a first circulation fluid channel 231, a second circulation fluid channel 232, and a second supply fluid channel 233 formed therein.

The first circulation fluid channel 231 may be provided as a channel through which the heat transfer medium circulates. The first circulation fluid channel 231 may be formed in a spiral shape inside the body 230. Alternatively, the first circulation fluid channel 231 may be disposed such that ring-shaped channels having different radii have the same center. Each of the first circulation fluid channel 231 may communicate with each other. The first circulation fluid channel 231 may be formed at the same height.

The second fluid channel 232 may be provided as a channel through which a cooling fluid circulates. The second circulation fluid channel 232 may be formed in a spiral shape inside the body 230. Alternatively, the second circulation fluid channel 232 may be disposed such that ring-shaped channels having different radii have the same center. Each of the second circulation fluid channel 232 may communicate with each other. The second circulation fluid channel 232 may have a cross-sectional area greater than that of the first circulation fluid channel 231. The second circulation fluid channel 232 may be formed at the same height. The second circulation fluid channel 232 may be located below the first circulation fluid channel 231.

The second supply fluid channel 233 may upwardly extend from the first circulation fluid channel 231 and may be provided to a top surface of the body 230. The second supply fluid channel 243 may be provided in a number corresponding to the first supply fluid channel 221, and may connect the first circulation fluid channel 231 to the first supply fluid channel 221.

The first circulation fluid channel 231 may be connected to a heat transfer medium storage unit 231a through a heat transfer medium supply line 231b. The heat transfer medium may be stored in the heat transfer medium storage unit 231a. The heat transfer medium may include an inert gas. According to an embodiment, the heat transfer medium may include a helium He gas. The helium gas may be supplied to the first circulation fluid channel 231 through the supply line 231b, and may be supplied to the bottom surface of the substrate W through the second supply fluid channel 233 and the first supply fluid channel 221 sequentially. The helium gas may serve as a medium through which a heat transferred from the plasma to the substrate W is transferred to the electrostatic chuck 210.

The second circulation fluid channel 232 may be connected to a cooling fluid storage unit 232a through a cooling fluid supply line 232c. The cooling fluid may be stored in the cooling fluid storage unit 232a. A cooler 232b may be provided within the cooling fluid storage unit 232a. The cooler 232b may cool the cooling fluid to a predetermined temperature. Alternatively, the cooler 232b may be installed at the cooling fluid supply line 232c. The cooling fluid supplied to the second circulation fluid channel 232 through the cooling fluid supply line 232c may circulate along the second circulation fluid channel 232 to cool the body 230. The body 230 may cool the dielectric plate 220 and the substrate W together to maintain the substrate W at a predetermined temperature.

The body 230 may include a metal plate. In an embodiment, all of the body 230 may be provided as a metal plate.

The focus ring 240 may be disposed in an edge region of the electrostatic chuck 210. The focus ring 240 may have a ring shape and may be disposed along the circumference of the dielectric plate 220. A top surface of the focus ring 240 may be positioned such that an outer portion 240a is higher than an inner portion 240b. The top surface inner portion 240b of the focus ring 240 may be positioned at the same height as the top surface of the dielectric plate 220. The inner portion 240b of the top surface of the focus ring 240 may support the edge region of the substrate W positioned outside the dielectric plate 220.

The outer portion 240a of the focus ring 240 may be provided to surround the edge region of the substrate W. The focus ring 240 may control the electromagnetic field so that the plasma density is uniformly distributed in an entire region of the substrate W. Accordingly, the plasma is uniformly formed over the entire area of the substrate S, so that each area of the substrate W may be uniformly etched.

The bottom cover 250 may be located at a bottom end of the substrate support unit 200. The bottom cover 250 may be positioned to be upwardly spaced apart from the bottom surface of the chamber 620. The bottom cover 250 may have a space 255 having an open top surface formed therein.

An outer radius of the bottom cover 250 may have a same length as an outer radius of the body 230. In an inner space 255 of the bottom cover 250, a lift pin module (not shown) or the like for moving a returned substrate W from an external transfer member to the electrostatic chuck 210 may be positioned. The lift pin module (not shown) may be spaced apart from the bottom cover 250 by a predetermined distance. A bottom surface of the bottom cover 250 may be made of a metal material. In the inner space 255 of the bottom cover 250, air may be provided. Since air has a dielectric constant lower than that of an insulator, it may serve to reduce the electromagnetic field inside the substrate support unit 200.

The bottom cover 250 may have a connection member 253. The connection member 253 may connect the outer surface of the bottom cover 250 to the inner wall of the chamber 620. A plurality of connection members 253 may be provided at the outer surface of the bottom cover 250 at regular intervals. The connection member 253 may support the substrate support unit 200 inside the chamber 620. In addition, the connection member 253 may be connected to the inner wall of the chamber 620 so that the bottom cover 250 is electrically grounded. A first power line 223c connected to the first power source 223a, a second power line 225c connected to the second power source 225a, and a heat transfer medium supply line 231b connected to the heat transfer medium storage unit 231a, etc may be extended within the bottom cover 250 through the inner space 255 of the connecting line.

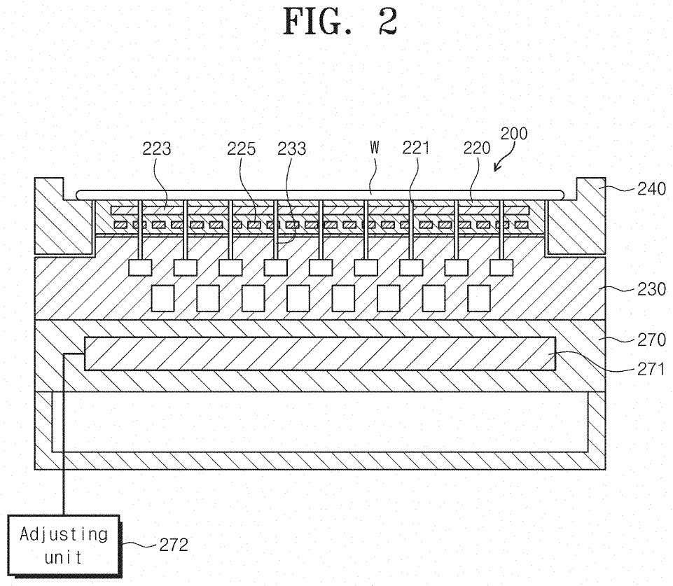

A plate 270 may be positioned between the electrostatic chuck 210 and the bottom cover 250. The plate 270 may cover a top surface of the bottom cover 250. The plate 270 may be provided with a cross-sectional area corresponding to the body 230. The plate 270 may include an insulator. According to an embodiment, one or more plates 270 may be provided. The plate 270 may serve to increase an electrical distance between the body 230 and the bottom cover 250. The plate 270 may be an insulation member. Referring the FIG. 2, an embodiment of the plate 270 will be explained further.

The shower head 300 may be positioned in the chamber 620 above the substrate support unit. The shower head may be placed to face the substrate support unit.

The shower head 300 may include a gas dispersion plate 310 and a support unit 330. The gas dispersion plate may be positioned spaced apart from a top surface to a bottom of the chamber 620. A predetermined space may be formed between the gas dispersion plate 310 and the top surface of the chamber 620. A thickness of the gas dispersion plate 310 may be provided in a predetermined plate form. A bottom surface of the gas dispersion plate 310 may have its surface anodic oxidation(anodizing) treated so an arc generation is prevented by a plasma. An end of the gas dispersion plate 310 may have a same form and a same cross-sectional area as that of the substrate support unit 200. The gas dispersion plate 310 may have a plurality of injection holes 311. The injection holes 311 may vertically penetrate the top surface and the bottom surface of the gas dispersion plate 310. The gas dispersion plate may include a metal material.

The support unit 330 may support a side part of the gas dispersion plate 310. The support plate 310 is connected to a top surface of the chamber 620, and a bottom surface is connected to a side of the gas dispersion plate 310. The support place may include a non-metal material.

The gas supply unit 400 may supply a process gas into the chamber 620. The gas supply unit 400 may include a gas supply nozzle 410, a gas supply line 420, and a gas storage unit 430. The gas supply nozzle 410 may be installed at a center of a top surface of the chamber 620. A spray hole may be formed at a bottom surface of the gas supply nozzle 410. The injection port may supply a process gas into the chamber 620. The gas supply line 420 may connect the gas supply nozzle 410 and the gas storage unit 430. The gas supply line 420 may supply the process gas stored in the gas storage unit 430 to the gas supply nozzle 410. A valve 421 may be installed at the gas supply line 420. The valve 421 may open and close the gas supply line 420 and control a flow rate of the process gas supplied through the gas supply line 420.

An exhaust baffle 500 may be positioned between the inner wall of the chamber 620 and the substrate support unit 200. The exhaust baffle 500 may be provided in an annular ring shape. A plurality of through holes 511 may be formed at the exhaust baffle 500. The process gas provided in the chamber 620 may pass through the through holes 511 of the exhaust baffle 500 and may be exhausted through the exhaust hole 102. A flow of the process gas may be controlled according to a shape of the exhaust baffle 500 and a shape of the through holes.

The plasma generation unit 600 may excite the process gas in the chamber 620 to a plasma state. According to an embodiment of the inventive concept, the plasma generation unit 600 may be configured in an inductively coupled plasma (ICP) type. In this case, as shown in FIG. 1, the plasma generation unit 600 may include a high frequency power source 610 for supplying a high frequency power, a first coil 621 and a second coil 622 electrically connected to the high frequency power source to receive the high frequency power.

The plasma generation unit 600 described herein is described as an inductively coupled plasma (ICP) type, but is not limited thereto and may be formed as a capacitively coupled plasma (CCP) type.

When a CCP type plasma source is used, the chamber 620 may include a top electrode and a bottom electrode, that is, a body.

The top electrode and the bottom electrode may be disposed parallel to each other in an up/down direction with a treating space therebetween. Not only the bottom electrode but also the top electrode may receive an energy for generating the plasma by receiving an RF signal by an RF power source, and the number of RF signals applied to each electrode is not limited to one as shown. An electric field is formed in a space between both electrodes, and the process gas supplied to the space may be excited in the plasma state. A substrate treatment process is performed using this plasma.

Referring back to FIG. 1, the first coil 621 and the second coil 622 may be disposed at positions facing the substrate W. For example, the first coil 621 and the second coil 622 may be installed on top of the chamber 620. A diameter of the first coil 621 is smaller than a diameter of the second coil 622, so it may be positioned at an inner part of a top of the chamber 620 and the second coil 622 may be positioned at on outer part of the top of the chamber 620. The first coil 621 and the second coil 622 may receive a high frequency power from a high frequency power source 610 to induce a time-varying magnetic field to the chamber, and thus the process gas supplied to the chamber 620 may be excited to the plasma.

Hereinafter, a process of treating a substrate using a substrate treating apparatus described above will be described.

When the substrate W is placed on the substrate support unit 200, a DC current may be applied from the first power source 223a to the first electrode 223. An electrostatic force may be applied between the first electrode 223 and the substrate W by the DC current applied to the first electrode 223, and the substrate W may be adsorbed to an electrostatic chuck 210 by the electrostatic force.

When the substrate W is adsorbed to the electrostatic chuck 210, a process gas may be supplied into the chamber 620 through a gas supply nozzle 410. The process gas may be uniformly injected into an inner region of the chamber 620 through an injection hole 311 of the shower head 300. A high frequency power generated from a high frequency power source may be applied to a plasma source, and thus the electromagnetic force may be generated in the chamber 620. The electromagnetic force may excite the process gas between the substrate support unit 200 and the shower head 300 with a plasma. The plasma may be provided to the substrate W to treat the substrate W. The plasma may perform an etching process.

FIG. 2 is a cross-sectional view illustrating a substrate treating apparatus according to an embodiment of the inventive concept in more detail.

In FIG. 2, a description of an overlapping portion with the substrate treating apparatus in FIG. 1 will be omitted. Referring to FIG. 2, the substrate treating apparatus in accordance with an embodiment of the inventive concept may contain an insulation member 270 having a space with a predetermined volume therein. The space 271 having a predetermined volume may be a fluid channel through which a fluid may communicate. According to an embodiment, the insulation member 270 may be positioned below the electrostatic chuck. According to an embodiment, the insulation member 270 may be a plate. In the following description of the inventive concept, the insulation member 270 and an isolator are used interchangeably.

According to an embodiment, the space 271 of the insulation member 270 may be provided in an empty state. According to an embodiment, the space 271 of the insulation member 270 may be provided filled with a predetermined volume. According to an embodiment, the space 271 of the insulation member 270 may be completely filled with a fluid.

In accordance with an embodiment, the substrate treating apparatus in accordance with this invention may further include an adjusting unit 272 capable of adjusting an injection amount of a fluid filling the space 271 in the insulation member 270. According to an embodiment, the adjusting unit 272 may be a chiller or a pump. According to an embodiment, the adjusting unit 272 may include both a chiller and a pump. The adjusting unit 272 may adjust an impedance by adjusting an amount of an air and a fluid and varying a ratio. The adjusting unit 272 may adjust the impedance of the chamber by adjusting the injection amount of the fluid. In this case, the fluid filling the space 271 may be a non-conducting liquid. According to an embodiment, the liquid injected into the space 271 may be an fc40. According to an embodiment, the liquid injected into the space 271 may be an fc3283. According to an embodiment, the fluid filling the space 271 may be provided as a liquid having a high insulation effect.

The adjusting unit 272 may change a state of a dielectric constant of the insulation member 270 by adjusting a fluid amount within the fluid channel. According to the inventive concept, a material composition within the fluid channel may be changed through a chiller or pump included in the adjusting unit 272. Through this, the impedance of the isolator may be changed during a process, thereby benefiting the process.

Although not illustrated in FIG. 2, in addition to the adjusting unit 272 capable of controlling the fluid, the substrate treating apparatus may further include a measuring unit (not illustrated) capable of measuring the impedance of the chamber. According to an embodiment, by measuring the impedance of the chamber in real-time, the measuring unit may control a fluid amount injected into the space 271 to have a desired impedance.

According to the inventive concept, a fluid channel is formed in a ceramic isolator that is, an insulation member 270, provided in a bottom part of the electrostatic chuck for an efficient use of the electrostatic chuck, thereby forming the space 271 and controlling an amount of the fluid included in the space 271, thereby changing the impedance of the entire chamber. According to an embodiment, the ceramic isolator may be an insulation member 270. A impedance of the insulation member 270 may be changed by controlling the amount of fluid injected into the fluid channel.

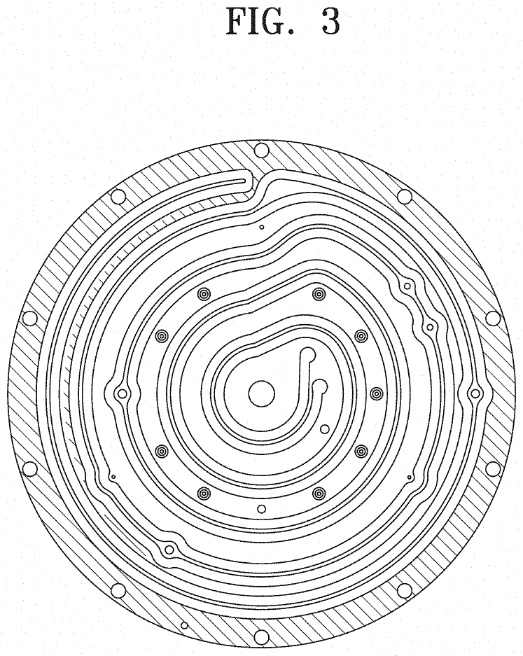

FIG. 3 illustrates an embodiment of forming a space 271 according to an embodiment of the inventive concept.

Referring to FIG. 3, an embodiment in which a fluid channel path pattern is formed on an insulation member 270 is disclosed. According to the inventive concept, by forming a fluid channel within an isolator and injecting a fluid or a gas into the fluid channel, a part of the isolator is made into an empty space 271, that is, a state having a predetermined dielectric constant in a vacuum dielectric constant 0 state, and thus an impedance matching may be actively controlled for TTTM(Tool To Tool Matching) of chambers. In addition, a process can be effectively performed by adjusting a dielectric constant of the isolator in a process step that requires a certain level of an impedance change between processes. According to an embodiment, a form of a fluid channel pattern may be variously formed.

In the case of the conventional technology, an existing isolator has a fixed dielectric constant after a sintering is completed, and thus there is a problem in that the dielectric constant is different according to the sintering conditions and materials of the isolator. In the conventional case, there is also a problem in that the ER gradient varies depending on the impedance of the isolator. Here, ER means an etching rate.

When the space 271 is formed by forming a fluid channel in the isolator according to the inventive concept, an impedance change may be induced according to a degree of filling of the space 271 in the isolator.

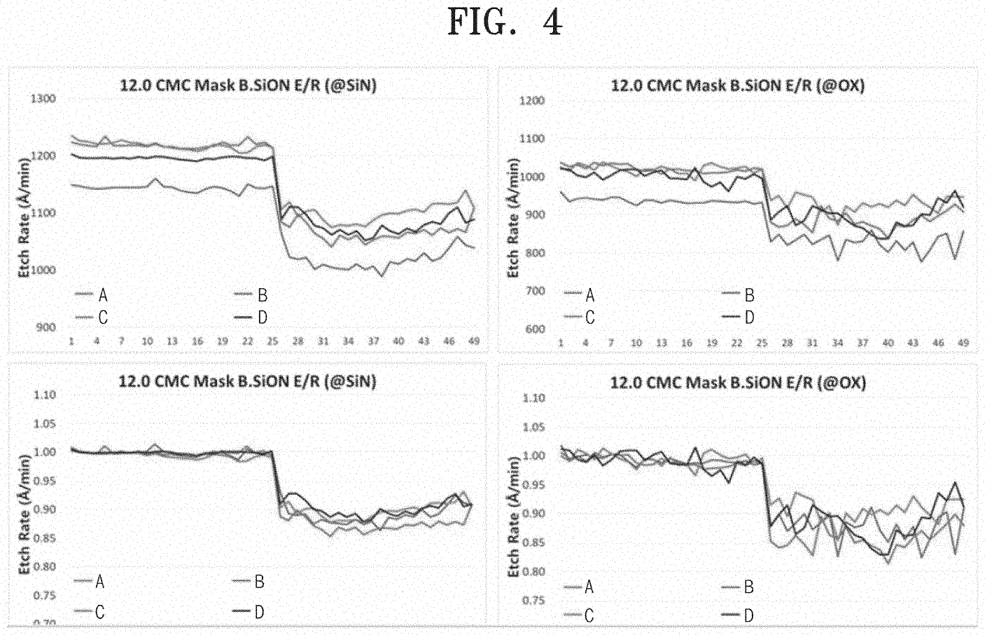

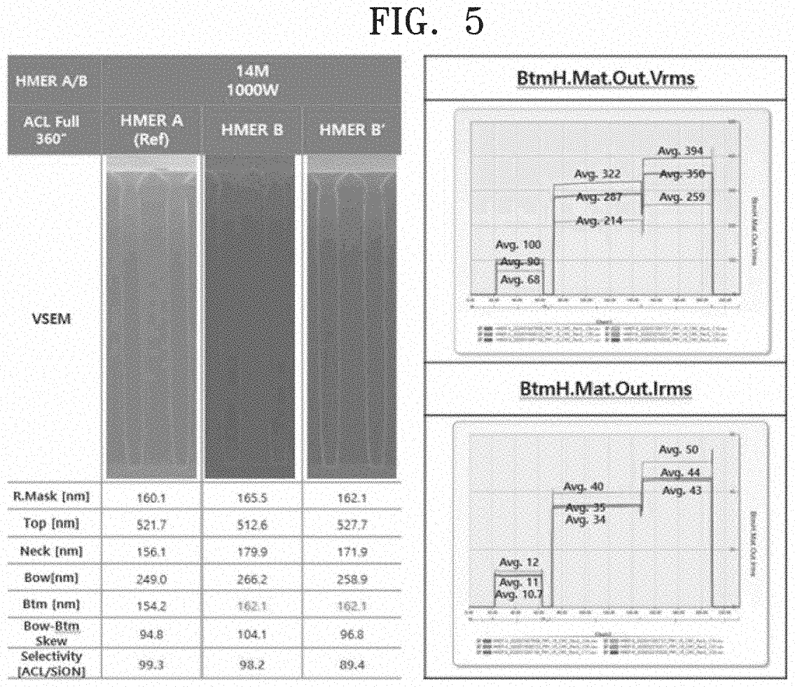

FIG. 4 to FIG. 5 illustrate a process change according to a thickness of the space 271 of the insulation member 270.

In more detail, FIG. 4 illustrates an ER change for each inner space 271 within the insulation member 270. FIG. 5 illustrates changes a CD change and a bias change for each inner space 271 within the insulation member 270. A CD means a critical dimension.

Referring to FIG. 4, an ER in accordance with an experimental example of dielectric constants of an inner space 271 of each insulation member 270 divided into embodiments A, B, C, and D, respectively, is disclosed. According to an embodiment, B indicates a case where Al2O3 is 100%, and A and D indicate a case where AL2O3 is 80% and AIR is 20%. C represents a 20% increase in power in the case of B. Referring to FIG. 4, it can be found that as the dielectric constant of the inner space 271 of the insulation member 270 decreases (AL2O3->AIR), the ER increases. In other words, in accordance with the inventive concept, it is possible to induce an impedance change by filling and emptying the inner space 271 of an isolator at a predetermined ratio by using the adjusting unit 272, that is, a chiller or a pump.

FIG. 5 shows a Vrms value, an Irms value, and a CH change and a bias change for each inner space of the isolator, respectively. Referring to FIG. 4 and FIG. 5, a bottom impedance change, an ER change, and a CD change occurs according to an amount of a material occupying the inner space 271 of the insulation member 270, thereby making it possible to use the material according to a situation.

The effects according to the inventive concept may be as follows. From a viewpoint of a TTTM of the chamber, it may be advantageous for the TTTM of the chamber to use an isolator which is variable than an isolator having a fixed dielectric constant value. In addition, in terms of improving a production efficiency of a facility, the inner change of the chamber due to an etching of a peripheral ring of the substrate may be controlled through a fluid according to the inventive concept to enable a using of the facility for a longer time. In addition, in terms of an entry to a facility process, for high-level processes that require various impedances, such a development can lead to a performing of a process of multiple conditions in a facility at once, or a performing of a process done with more precision.

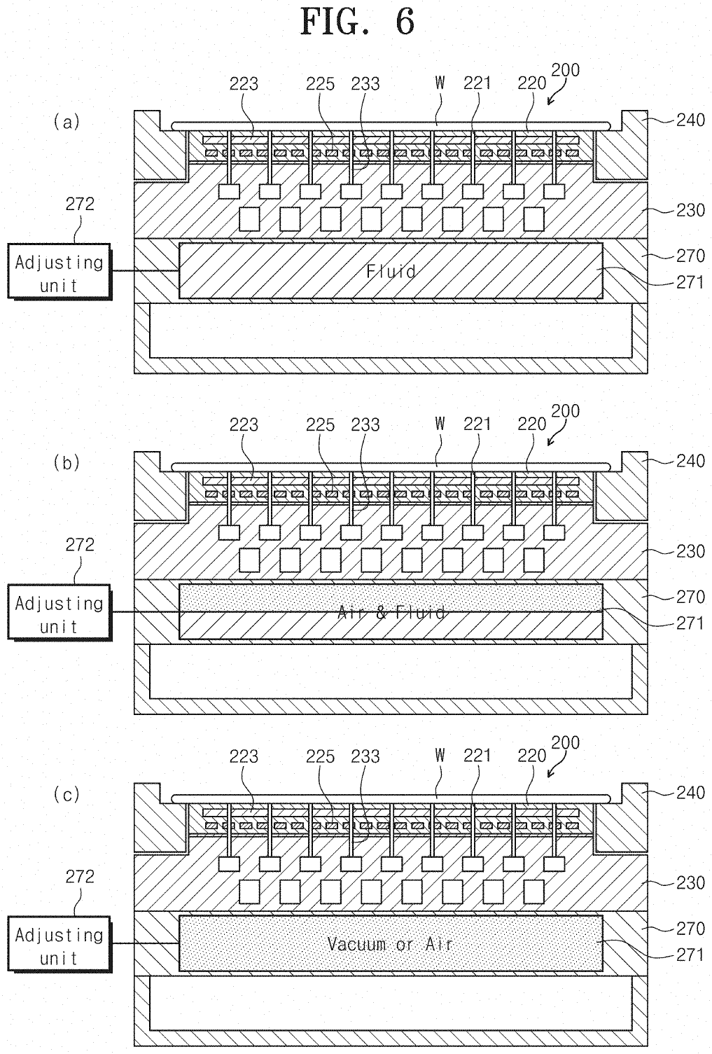

FIG. 6 illustrates a space 271 within an insulation member 270 according to various embodiments of the inventive concept.

Referring to FIG. 6(a), a fluid channel is configured in the isolator, and a dielectric constant is adjusted by changing the inner space 271 of the isolator to a condition that fills a fluid in a vacuum, thereby changing an impedance of a chamber to efficiently perform a process.

In FIG. 6, when a fluid having a higher dielectric constant than the isolator is used to control the isolator, electrical characteristics of the isolator become stronger and cause an impedance weakening, thereby reducing an ER level. and when a fluid having a lower dielectric constant than the isolator is used, the ER level of the isolator may be induced to be higher.

Although only an embodiment in which the fluid is filling, half filling, or not in the space 271 is disclosed in FIG. 6(a) to FIG. 6(c), the inventive concept is not limited thereto and the fluid may be adjusted to have various volumes in the space 271.

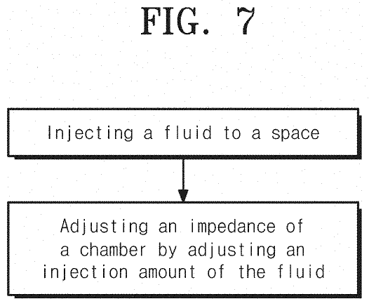

FIG. 7 is a flowchart illustrating a substrate treating method according to an embodiment of the inventive concept.

In accordance with the inventive concept, a step of injecting a fluid into a space 271 in an insulation member 270, and a step of adjusting an impedance of a chamber by adjusting an injection amount of the fluid may be included.

According to an embodiment, the impedance of the chamber may be adjusted simultaneously with a substrate treatment. That is, while treating a substrate, the impedance may be changed in real time while adjusting the injection amount of the fluid. The inventive concept may change the impedance of the chamber by controlling an amount of a material filling the inner space 271 of a bottom isolator of the chamber, thereby facilitating a TTTM between chambers and an entry to high-level processes.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a chamber having a space for treating a substrate therein;
a support unit for supporting the substrate within the chamber; and
an insulation member having a space of a predetermined volume therein.

2. The substrate treating apparatus of claim 1, wherein the space is empty.

3. The substrate treating apparatus of claim 1, wherein a fluid is provided in a predetermined volume at the space.

4. The substrate treating apparatus of claim 1, wherein the space is filled with a fluid.

5. The substrate treating apparatus of claim 2, further comprising an adjusting unit for adjusting an injection amount of a fluid injected into the space.

6. The substrate treating apparatus of claim 5, wherein the adjusting unit adjusts the injection amount of the fluid so an impedance of the chamber is adjusted.

7. The substrate treating apparatus of claim 5, wherein the adjusting unit is a chiller or a pump.

8. A substrate treating apparatus comprising:
a chamber having a space for treating a substrate therein;
a support unit for supporting the substrate within the chamber, and including an electrostatic chuck for adsorbing the substrate using an electrostatic force;
a gas supply unit for supplying a treating gas within the space;
a plasma source for generating a plasma from the treating gas; and
an insulation member positioned below the electrostatic chuck, and having a space of a predetermined volume therein.

9. The substrate treating apparatus of claim 8, wherein the space is empty.

10. The substrate treating apparatus of claim 8, wherein a fluid is provided in a predetermined volume at the space.

11. The substrate treating apparatus of claim 8, wherein the space is filled with a fluid.

12. The substrate treating apparatus of claim 9, further comprising an adjusting unit for adjusting an injection amount of a fluid injected to the space.

13. The substrate treating apparatus of claim 12, wherein the adjusting unit adjusts the injection amount of the fluid so an impedance of the chamber is adjusted.

14. The substrate treating apparatus of claim 12, wherein the adjusting unit is a chiller or a pump.

15. The substrate treating apparatus of claim 10, wherein the fluid is a non-conducting liquid.

16-20. (canceled)
